(19) United States
(12) Patent Application Publication
(10) Pub. No.: US 2024/0334586 A1
(43) Pub. Date: Oct. 3, 2024

(54) PACKAGE STRUCTURE

(71) Applicant: Advanced Semiconductor Engineering, Inc., Kaohsiung (TW)

(72) Inventors: An-Hsuan HSU, Kaohsiung (TW); Hung-Hsien HUANG, Kaohsiung (TW); Chin-Li KAO, Kaohsiung (TW)

(73) Assignee: Advanced Semiconductor Engineering, Inc., Kaohsiung (TW)

(21) Appl. No.: 18/129,768

(22) Filed: Mar. 31, 2023

(51) Int. Cl. H05K 1/02; H05K 3/10; H05K 5/00

(52) U.S. Cl. CPC H05K 1/0201; H05K 3/103; H05K 5/0091

(57) ABSTRACT

A package structure is provided. The package structure includes an electronic component, a heat dissipating element, a thermal interfacing unit, and a confining structure. The electronic component has an upper surface. The heat dissipating element is over the upper surface of the electronic component. The thermal interfacing unit is between the upper surface of the electronic component and the heat dissipating element. The thermal interfacing unit includes a thermal interfacing material (TIM). The TIM is attached to the confining structure by capillary force.

### BACKGROUND

### 1. Field of the Disclosure

The present disclosure relates to a package structure, and particularly to a package structure including a thermal interfacing unit.

### 2. Description of the Related Art

In a conventional package structure, a thermal interfacing material (TIM) is utilized to transmit heat of an electronic component to a heat dissipating element. However, the flowable portion of the TIM (e.g., heat dissipating paste, liquid metal at room temperature, etc.) may overflow to an area exterior to the electronic component due to warpage of the die, or breakage of a dam structure confining the TIM, which deteriorates the performance of the electrical connection in the package as well as the thermal dissipation efficiency. Therefore, a new package structure is required to address the aforesaid issues.

### SUMMARY

In some embodiments, a package structure includes an electronic component, a heat dissipating element, a thermal interfacing unit, and a confining structure. The electronic component has an upper surface. The heat dissipating element is over the upper surface of the electronic component. The thermal interfacing unit is between the upper surface of the electronic component and the heat dissipating element. The thermal interfacing unit includes a thermal interfacing material (TIM). The TIM is attached to the confining structure by capillary force.

In some embodiments, a package structure includes an electronic component, a heat dissipating element, and a supporting structure. The electronic component has an upper surface. The heat dissipating element is over the upper surface of the electronic component. The supporting structure includes a plurality of wires configured to reduce the heat dissipating element from being angled with the upper surface of the electronic component.

In some embodiments, a package structure includes a carrier, an electronic component, a heat dissipating element, and a thermal conductive uniformer. The carrier has a warpage. The electronic component is disposed over the carrier and conforms to the warpage. The heat dissipating element is on the carrier and covers the electronic component. The thermal conductive uniformer is configured to provide homogeneous thermal conductivity between the electronic component and the heat dissipating element.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of a package structure according to some embodiments of the present disclosure.

FIG. 2 illustrates a cross-sectional view of an example of a package structure according to some embodiments of the present disclosure.

FIG. 3 illustrates a cross-sectional view of an example of a package structure according to some embodiments of the present disclosure.

FIG. 4 illustrates a cross-sectional view of an example of a package structure according to some embodiments of the present disclosure.

FIG. 5 illustrates a cross-sectional view of an example of a package structure according to some embodiments of the present disclosure.

FIG. 6 illustrates a cross-sectional view of an example of a package structure according to some embodiments of the present disclosure.

FIG. 7A illustrates a partial enlarged view of an example of a package structure according to some embodiments of the present disclosure.

FIG. 7B illustrates a partial enlarged view of an example of a package structure according to some embodiments of the present disclosure.

FIG. 7C illustrates a partial enlarged view of an example of a package structure according to some embodiments of the present disclosure.

FIG. 7D illustrates a partial enlarged view of an example of a package structure according to some embodiments of the present disclosure.

FIG. 8A illustrates a partial enlarged view of an example of a package structure according to some embodiments of the present disclosure.

FIG. 8B illustrates a partial enlarged view of an example of a package structure according to some embodiments of the present disclosure.

FIG. 9 illustrates a partial enlarged view of an example of a package structure according to some embodiments of the present disclosure.

FIG. 10 illustrates a partial enlarged view of an example of a package structure according to some embodiments of the present disclosure.

FIG. 11A illustrates a cross-sectional view of an example of a package structure according to some embodiments of the present disclosure.

FIG. 11B illustrates a cross-sectional view of an example of a package structure according to some embodiments of the present disclosure.

FIG. 12 illustrates a partial enlarged view of an example of a package structure according to some embodiments of the present disclosure.

FIG. 13A illustrates one or more stages of an example of a method for manufacturing a confining structure according to some embodiments of the present disclosure.

FIG. 13B illustrates one or more stages of an example of a method for manufacturing a confining structure according to some embodiments of the present disclosure.

FIG. 13C illustrates one or more stages of an example of a method for manufacturing a confining structure according to some embodiments of the present disclosure.

FIG. 14A illustrates one or more stages of an example of a method for manufacturing a confining structure according to some embodiments of the present disclosure.

FIG. 14B illustrates one or more stages of an example of a method for manufacturing a confining structure according to some embodiments of the present disclosure.

FIG. 14C illustrates one or more stages of an example of a method for manufacturing a confining structure according to some embodiments of the present disclosure.

FIG. 14D illustrates one or more stages of an example of a method for manufacturing a confining structure according to some embodiments of the present disclosure.

FIG. 14E illustrates one or more stages of an example of a method for manufacturing a confining structure according to some embodiments of the present disclosure.

FIG. 15A illustrates one or more stages of an example of a method for manufacturing a confining structure according to some embodiments of the present disclosure.

FIG. 15B illustrates one or more stages of an example of a method for manufacturing a confining structure according to some embodiments of the present disclosure.

FIG. 15C illustrates one or more stages of an example of a method for manufacturing a confining structure according to some embodiments of the present disclosure.

FIG. 15D illustrates one or more stages of an example of a method for manufacturing a confining structure according to some embodiments of the present disclosure.

FIG. 15E illustrates one or more stages of an example of a method for manufacturing a confining structure according to some embodiments of the present disclosure.

Common reference numerals are used throughout the drawings and the detailed description to indicate the same or similar components. Embodiments of the present disclosure will be readily understood from the following detailed description taken in conjunction with the accompanying drawings.

### DETAILED DESCRIPTION

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

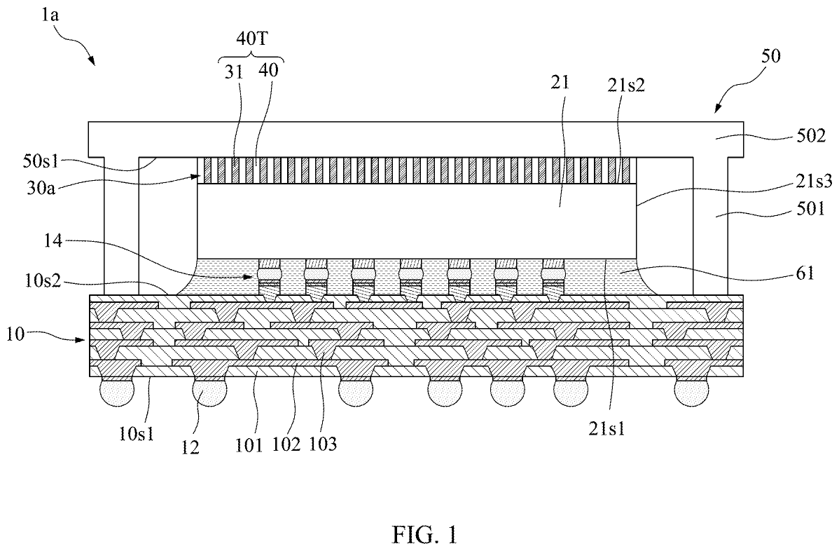

FIG. 1 illustrates a cross-sectional view of a package structure 1a according to some embodiments of the present disclosure. In some embodiments, the package structure 1a may include a carrier 10, an electronic component 21, a confining structure 30a, a thermal interfacing material (TIM) 40, a heat dissipating element 50, and an underfill 61.

The carrier 10 may include a redistribution structure, which includes one or more dielectric layers 101, one or more conductive traces 102, and one or more conductive vias 103. The dielectric layer 101 may include an insulating material, a passivation material, a dielectric material or a solder resist material, such as, for example, a benzocyclobutene (BCB) based polymer or a polyimide (PI). In some embodiments, the dielectric layer 101 may be made of a photoimageable material. The conductive trace 102 may be disposed on or disposed over a surface (e.g., a top surface or a bottom surface) of the dielectric layer 101. The conductive via 103 may be disposed on or disposed over a surface (e.g., a top surface or a bottom surface) of the conductive trace 102. Each of the conductive vias 103 may penetrate the corresponding dielectric layer 101. The material of the conductive trace 102 and the conductive via 103 may include, for example, copper, aluminum, titanium, another conductive metal, or an alloy thereof. The carrier 10 may include a surface 10s1 (or a bottom surface) and a surface 10s2 (or a top surface) opposite to the surface 10s1. The bottom surface of the bottommost dielectric layer 101 may be defined as the surface 10s1 of the carrier 10. The top surface of the topmost dielectric layer 101 may be defined as the surface 10s2 of the carrier 10. In some embodiments, the carrier 10 may include a printed circuit board (PCB), an interposer, or other suitable carriers.

In some embodiments, the package structure 1a may include electrical connections 12. The electrical connection 12 may be disposed on or disposed over the surface 10s1 of the carrier 10. The electrical connection 12 may include electrical contacts, such as solder balls, conductive bumps, or the like. The electrical connection 12 may include alloys of gold and tin solder or alloys of silver and tin solder.

The electronic component 21 may be disposed on or disposed over the surface 10s2 of the carrier 10. The electronic component 21 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 21 may include a system on chip (SoC). For example, the electronic component 21 may include a radiofrequency IC (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. The electronic component 21 may have a surface 21s1 (or a bottom surface) and a surface 21s2 (or a top surface) opposite to the surface 21s1. The surface 21s1 may face the carrier 10 and function as an active surface of the electronic component 21. The surface 21s2 may function as a backside surface of the electronic component 21. The electronic component 21 may have a surface 21s3 (or a lateral surface) extending between the surfaces 21s1 and 21s2.

The package structure 1a may include electrical connections 14. The electrical connection 14 may be disposed on or disposed over the surface 21s1 of the electronic component 21. The electrical connection 14 may be disposed between the surface 10s2 of the carrier 10 and the surface 21s1 of electronic component 21. The electrical connection 14 may be configured to electrically connect the carrier 10 and the electronic component 21. In some embodiments, each of the electrical connections 14 may include a pad, a solder ball, and/or other suitable conductive elements. The pad may include, for example, copper, aluminum, titanium, another conductive metal, or an alloy thereof. The solder ball may include such as alloys of gold and tin solder or alloys of silver and tin solder.

In some embodiments, the confining structure 30a may be disposed on or disposed over the surface 21s2 of the electronic component 21. In some embodiments, the confining structure 30a may cover the surface 21s2 of the electronic component 21. In some embodiments, the confining structure 30a may contact the surface 21s2 of the electronic component 21. In some embodiments, the confining structure 30a may be disposed between the electronic component 21 and the heat dissipating element 50. In some embodiments, the confining structure 30a may be configured to confine the TIM 40, such as a thermal conductive paste, liquid thermal conductive material, or other suitable materials so that the TIM 40 may be confined within a desired region to reduce the TIM 40 overflowing to an area exterior to a desired region. In some embodiments, the confining structure 30a may be configured to reduce or prevent the TIM 40 from overflowing to an area exterior to the electronic component 21. More specifically, the confining structure 30a may be configured to reduce or prevent TIM 40 overflowing to the surface 10s2 of the carrier 10, which contaminates the carrier 10. In some embodiments, the confining structure 30a may be configured to reduce or prevent the heat dissipating element 50 from being angled with respect to the surface 21s2 of the electronic component 21. More specifically, the confining structure 30a may be configured to reduce or prevent a bottom surface (e.g., 50s1) of the heat dissipating element 50 from being angled with respect to the surface 21s2 of the electronic component 21. In some embodiments, the thickness of the confining structure 30a is thinner than about 150 μm.

In some embodiments, the confining structure 30a may include a 1-dimensional feature 31. For example, the 1-dimensional feature 31 may include a plurality of wires extending in a unidirectional manner, for instance, extending in a direction perpendicular to the surface 21s2 of the electronic component 21. Each of the wires may have a length greater than a width along the extending direction of the wire. In some embodiments, each of the plurality of wires may include a nano-scale dimension and can be nanowires. The 1-dimensional feature 31 (or wires) may have a dimension (e.g., diameter, width, and/or aperture) equal to or less than 1000 nm, such as 1000 nm, 500 nm, 100 nm, 50 nm, 30 nm, 10 nm, 5 nm, or less. In some embodiments, the nanowires of the 1-dimensional feature 31 may have a substantially uniform pitch. The 1-dimensional feature 31 may extend between electronic component 21 and the heat dissipating element 50. For example, the wires of the 1-dimensional feature 31 may extend from the electronic component 21 toward the heat dissipating element 50 or extend from the heat dissipating element 50 toward the electronic component 21. In some embodiments, the 1-dimensional feature 31 may contact the TIM 40. In some embodiments, the TIM 40 may be attached to the 1-dimensional feature 31 of the confining structure 30a by capillary force. In other words, the TIM 40 may be attached to the material of some wires of the confining structure 30a by capillary force. Further, the 1-dimensional feature 31 (or wires) may provide a sufficient surface area, which increases the capillary force between the 1-dimensional feature 31 and the TIM 40. For example, the 1-dimensional feature 31 (or wires) may include a surface area causing sufficient capillary force to confine the TIM 40. The 1-dimensional feature 31 may include a sufficient surface area to cause capillary force interacting with the TIM 40. Further, the 1-dimensional feature 31 may have a relatively great thermal conductivity. Therefore, the 1-dimensional feature 31 may be configured to transmit heat from the electronic component 21 to the heat dissipating element 50. In some embodiments, the 1-dimensional feature 31 may include metal, such as silver, gold, aluminum, copper, nickel, or other suitable materials. In some embodiments, the 1-dimensional feature 31 may include alloy, such as copper-nickel alloy, copper-gold alloy, nickel-titanium alloy, nickel-gold alloy, gold-platinum alloy, silver-platinum alloy, or other suitable materials. In some embodiments, the 1-dimensional feature 31 may include insulative materials, such as silicon oxide, titanium oxide, zinc oxide, tungsten oxide, copper sulfide, or other suitable materials.

In some embodiments, the TIM 40 may be disposed on or disposed over the surface 21s2 of the electronic component 21. In some embodiments, the TIM 40 may cover the surface 21s2 of the electronic component 21. In some embodiments, the TIM 40 may contact the surface 21s2 of the electronic component 21. In some embodiments, the TIM 40 may be disposed between the electronic component 21 and the heat dissipating element 50. In some embodiments, the TIM 40 may surround a portion of the confining structure 30a. In some embodiments, the TIM 40 may surround the 1-dimensional feature 31 (or wires). In some embodiments, the TIM 40 may be configured to transmit a heat (not shown) generated from the electronic component 21 toward the heat dissipating element 50. The thermal conductivity of the TIM 40 may be equal to or greater than 5 W/mK. The TIM 40 may include, for example, silicone, metal, alloy, or other suitable materials. Suitable fillers, such as metal oxide (e.g., aluminum oxide) may also be included. In some embodiments, the TIM 40 may be attached to the 1-dimensional feature 31 (or wires) and the TIM 40 may have a length greater than a width along the extending direction of the 1-dimensional feature 31 (or wires).

In some embodiments, the confining structure 30a and the TIM 40 may collectively function as a thermal interfacing unit 40T, which is configured to transmit a heat between the electronic component 21 and the heat dissipating element 50. In some embodiments, the thermal interfacing unit 40T may function as a supporting structure, which may conform to the warpage of the carrier 10 and prevent the heat dissipating element 50 from being angled with respect to the surface 21s2 of the electronic component 21. In some embodiments, the thermal interfacing unit 40T may function as a thermal conductive uniformer, which is configured to provide homogeneous thermal conductivity between the electronic component 21 and the heat dissipating element 50.

In some embodiments, the heat dissipating element 50 may be disposed on or disposed over the surface 21s2 of the electronic component 21. In some embodiments, the heat dissipating element 50 may be disposed on or disposed over the confining structure 30a. In some embodiments, the heat dissipating element 50 may be in contact with the confining structure 30a. In some embodiments, the heat dissipating element 50 may be in contact with the 1-dimensional feature 31 (or wires). In some embodiments, the heat dissipating element 50 may be spaced apart from the electronic component 21 by the confining structure 30a. In some embodiments, the heat dissipating element 50 may be disposed on or disposed over the TIM 40. In some embodiments, the heat dissipating element 50 may be in contact with the TIM 40. In some embodiments, the heat dissipating element 50 may be spaced apart from the electronic component 21 by the TIM 40. The heat dissipating element 50 may be configured to transmit a heat of the package structure 1a to the environment. The heat dissipating element 50 may include, for example, a solid metal slug or an electrical insulator coated with metallic film. The heat dissipating element 50 may have a surface 50s1 (or a bottom surface) facing the electronic component 21. In some embodiments, the surface 50s1 of the heat dissipating element 50 may be substantially parallel to the surface 21s2 of the electronic component 21.

The heat dissipating element 50 may include a portion 501 and a portion 502. The portion 501 may face the surface 21s3 of the electronic component 21. The portion 502 may cover the surface 21s2 of the electronic component 21. In some embodiments, the confining structure 30a may be in contact with the portion 502 of the heat dissipating element 50. In some embodiments, the 1-dimensional feature 31 may be in contact with the portion 502 of the heat dissipating element 50. In some embodiments, the thermal interfacing unit 40T may be configured to prevent the portion 502 of the heat dissipating element 50 from being angled with respect to the surface 21s2 of the electronic component 21. Since the 1-dimensional feature 31 (or wires) of the thermal interfacing unit 40T has a substantially uniform pitch, the 1-dimensional feature 31 (or wires) may provide a uniform supporting force over the electronic component 21. As a result, the heat dissipating element 50 may be supported by the 1-dimensional feature 31 (or wires) and prevented from being angled with the electronic component 21 by said uniform supporting force during a process of pressing the heat dissipating element 50 to the carrier 10.

The underfill 61 may cover the surface 21s1 of the electronic component 21. The underfill 61 may encapsulate the electrical connection 14. The underfill 61 may include a Novolac-based resin, an epoxy-based resin, a silicone-based resin, or another suitable material.

In a comparative example, a TIM may overflow to an area exterior to an electronic component because of the warpage of the overall structure, which results in an inhomogeneous thermal conductivity between the electronic component and a heat dissipating element. As a result, the performance of the heat transmission is degraded. In another comparative example, a block spacer is disposed between an electronic component and a heat dissipating element. A TIM is disposed within the block spacer. Such block spacer may deform due to the warpage of the overall structure, which causes the TIM overflow to an area exterior to the electronic component and thus degrades the performance of the heat transmission. In the embodiments of the present disclosure, the package structure 1a includes the confining structure 30a, which may include a 1-dimensional feature 31 (e.g., wires). The TIM 40 may be attached to the 1-dimensional feature 31 through capillary force, which prevents the TIM 40 from overflowing to an area exterior to the electronic component 21. Further, the confining structure 30a may conform to the warpage of the carrier 10, which prevents the heat dissipating element 50 from being angled with respect to the electronic component 21. Moreover, even some of 1-dimensional feature 31 (e.g., wires) of the confining structure 30a are destroyed due to the warpage, the remaining wires can provide a sufficient surface area to cause the TIM 40 to be confined by capillary force.

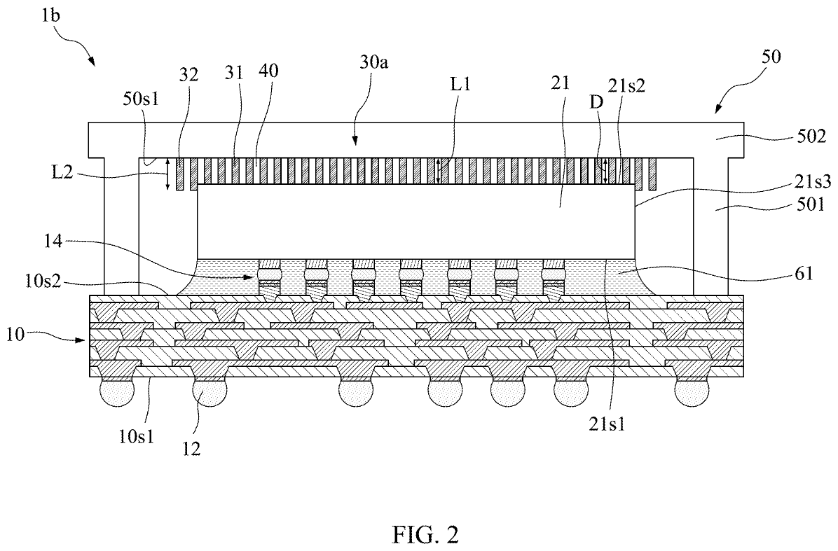

FIG. 2 illustrates a cross-sectional view of an example of a package structure 1b according to some embodiments of the present disclosure. The package structure 1b is similar to the package structure 1a as shown in FIG. 1, and the differences therebetween are described below.

In some embodiments, the confining structure 30a may further include a 1-dimensional feature 32. The material and the composition of the 1-dimensional feature 32 may be the same as or similar to those of the 1-dimensional feature 31. In some embodiments, the 1-dimensional feature 32 may include a plurality of nanowires. In some embodiments, the 1-dimensional feature 32 may disposed on or disposed over the surface 50s1 of the heat dissipating element 50. In some embodiments, a portion of the confining structure 30a (e.g., 1-dimensional feature 32) may downwardly extend to the surface 20s3 (or lateral side) of the electronic component 21. In some embodiments, the 1-dimensional feature 32 may be spaced apart from the surface 21s2 of the electronic component 21. In some embodiments, the 1-dimensional feature 32 may cover a portion of the surface 21s3 of the electronic component 21. The 1-dimensional feature 31 (or nanowire) may have a length L1. The 1-dimensional feature 32 (or nanowire) may have a length L2. In some embodiments, the length L2 of the 1-dimensional feature 32 may be greater than the a distance D between the surface 50s1 of the heat dissipating element 50 and the surface 21s1 of the electronic component 21. In some embodiments, the length L2 of the 1-dimensional feature 32 may be greater than the length L1 of the 1-dimensional feature 31. In some embodiments, the 1-dimensional feature 32 may be configured to transmit heat from the electronic component 21, which improves the performance of heat transmission. In some embodiments, the 1-dimensional feature 32 (or wires) may extend to and/or contact the surface 21s3 of the electronic component 21, which improves the performance of the heat dissipating from surface 21s3 of the electronic component 21.

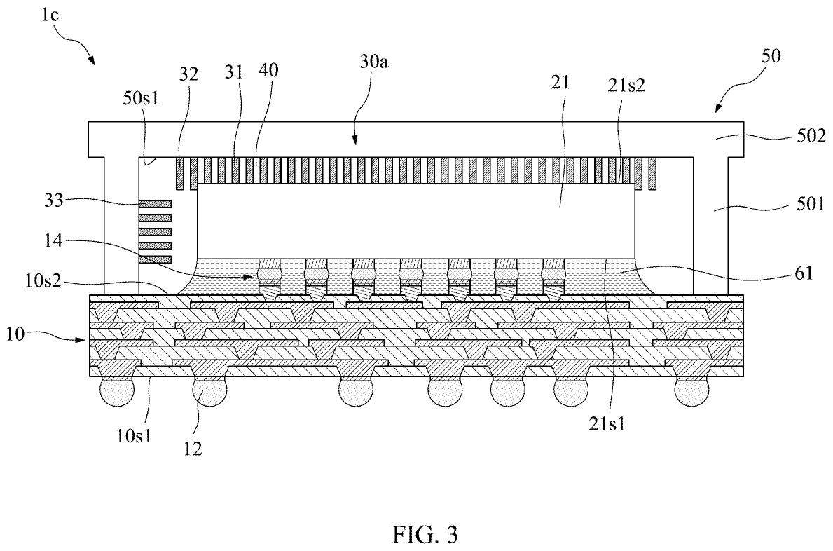

FIG. 3 illustrates a cross-sectional view of an example of a package structure 1c according to some embodiments of the present disclosure. The package structure 1c is similar to the package structure 1b as shown in FIG. 2, and the differences therebetween are described below.

In some embodiments, the package structure 1c may include a 1-dimensional feature 33. The composition and the material of the 1-dimensional feature 33 may be the same as or similar to those of the 1-dimensional feature 31. In some embodiments, the 1-dimensional feature 33 may include a plurality of nanowires. In some embodiments, the 1-dimensional feature 33 may be disposed on or disposed over the portion 501 of the heat dissipating element 50. In some embodiments, the 1-dimensional feature 33 may be in contact with the portion 501 of the heat dissipating element 50. In some embodiments, the 1-dimensional feature 33 may be laterally protruded from the portion 501 toward the surface 21s3 of the electronic component 21. The 1-dimensional feature 33 may be spaced apart from the electronic component 21. In some embodiments, the length of the 1-dimensional feature 33 may be equal to or greater than the length of the 1-dimensional feature 31. In some embodiments, the 1-dimensional feature 33 may provide an additional heat transmission path, which improves the performance of heat transmission. The 1-dimensional feature 33 may provide a lateral heat dissipating path different from that provided by the 1-dimensional feature 32, which improves the performance of heat dissipating.

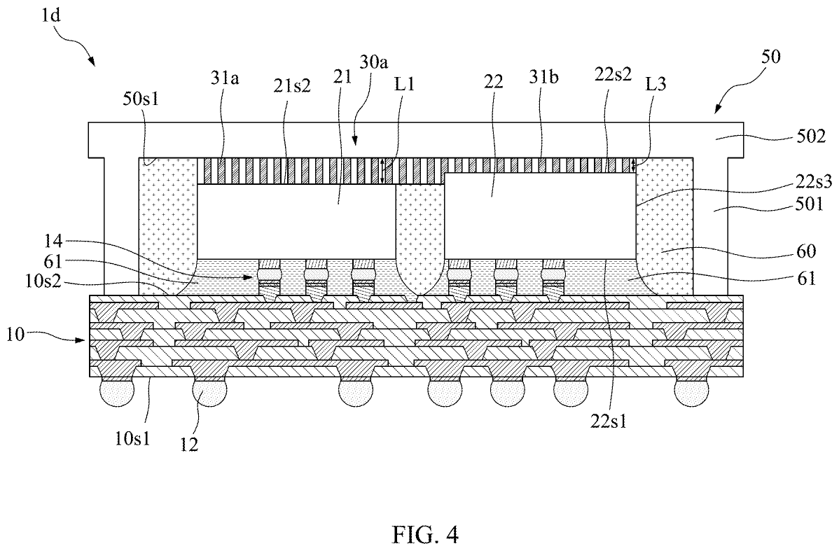

FIG. 4 illustrates a cross-sectional view of an example of a package structure 1d according to some embodiments of the present disclosure. The package structure 1d is similar to the package structure 1a as shown in FIG. 1, and the differences therebetween are described below.

In some embodiments, the package structure 1d may further include an electronic component 22. The electronic component 22 may be disposed on or disposed over the surface 10s2 of the carrier 10. The electronic component 22 may be a chip or a die including a semiconductor substrate, one or more IC devices and one or more overlying interconnection structures therein. For example, the electronic component 22 may include a SoC. For example, the electronic component 22 may include an RFIC, an ASIC, a CPU, a MPU, a GPU, a MCU, a FPGA, or another type of IC. The electronic component 22 may have a surface 22s1 (or a bottom surface) and a surface 22s2 (or a top surface) opposite to the surface 22s1. The electronic component 22 may have a surface 22s3 (or a lateral surface) extending between the surfaces 22s1 and 22s2. In some embodiments, the electronic components 21 and 22 may be arranged side by side. In some embodiments, the surface 21s2 of the electronic component 21 may be located at a level different from that of the surface 22s2 of the electronic component 22.

In some embodiments, the confining structure 30a may further include wires 31a and 31b. Each of the wires 31a and 31b may include a nanowire. The wire 31a may extend between electronic component 21 and the heat dissipating element 50. The wire 31b may extend between electronic component 22 and the heat dissipating element 50. The wire 31b may have a length L3. In some embodiments, the length L3 of the wire 31b may be different from the length L1 of the wire 31a. In some embodiments, the wire 31a may laterally overlap the surface 22s3 of the electronic component 22. In some embodiments, the wire 31a may be in contact with the surface 22s3 of the electronic component 22. In some embodiments, the TIM 40 may be in contact with the surface 22s3 of the electronic component 22.

In some embodiments, the confining structure 30a may further include an encapsulant 60. The encapsulant 60 may be disposed on or disposed over the surface 10s2 of the carrier 10. The encapsulant 60 may encapsulate the electronic component 21. In some embodiments, the encapsulant 60 may encapsulate the confining structure 30a. In some embodiments, the encapsulant 60 may encapsulate the 1-dimensional features 31a and 31b (or wires 31a and 31b). The encapsulant 60 may include a Novolac-based resin, an epoxy-based resin, a silicone-based resin, or another suitable material. Suitable fillers may also be included, such as powdered SiO₂.

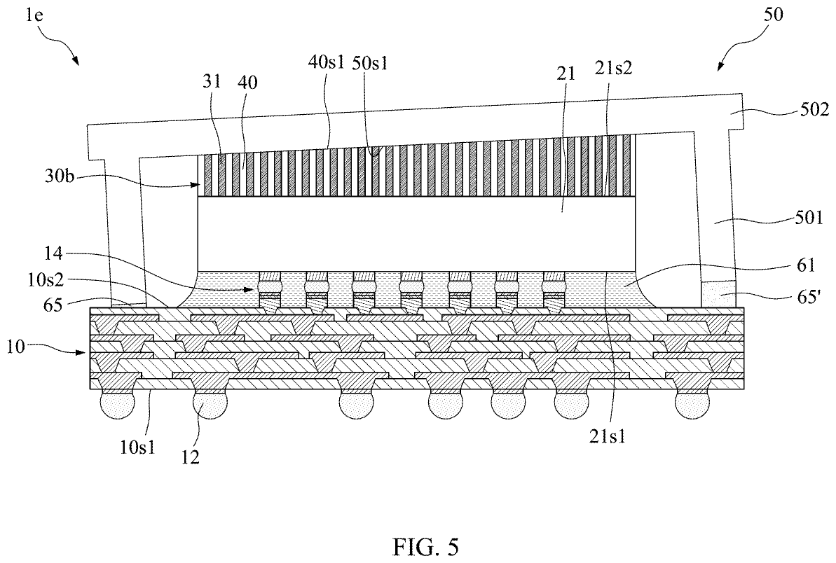

FIG. 5 illustrates a cross-sectional view of an example of a package structure 1e according to some embodiments of the present disclosure. The package structure 1e is similar to the package structure 1a as shown in FIG. 1, and the differences therebetween are described below.

In some embodiments, the package structure 1e may include a confining structure 30b. In some embodiments, the 1-dimensional feature 31 of the confining structure 30b may have different lengths. In some embodiments, the surface 50s1 of the heat dissipating element 50 may be angled with respect to the surface 21s2 of the electronic component 21. The portion 502 of the heat dissipating element 50 may be slanted with respect to the surface 21s2 of the electronic component 21. The portion 501 of the heat dissipating element 50 may be slanted with respect to the surface 10s2 of the carrier 10. The heat dissipating element 51 may be attached to the carrier 10 by adhesives 65 and 65′. The adhesive 65 may have a thickness different from that of the adhesive 65′. In some embodiments, the TIM 40 may have uneven thickness. The TIM 40 may have a surface 40s1 (or a top surface). The surface 40s1 of the TIM 40 may face the heat dissipating element 50. The surface 40s1 of the TIM 40 may be in contact with the heat dissipating element 50. In some embodiments, the surface 40s1 of the TIM 40 may be angled with respect to the surface 21s2 of the electronic component 21.

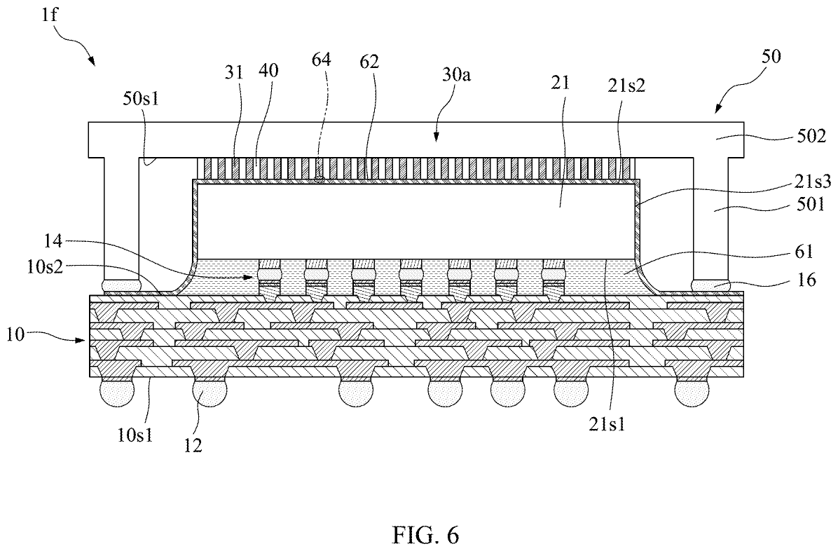

FIG. 6 illustrates a cross-sectional view of an example of a package structure 1f according to some embodiments of the present disclosure. The package structure 1f is similar to the package structure 1a as shown in FIG. 1, and the differences therebetween are described below.

In some embodiments, the package structure 1f may include a metallic layer 62. In some embodiments, the metallic layer 62 may be disposed on or disposed over the surface 21s2 of the electronic component 21. The metallic layer 62 contact the underfill 61 and the carrier 10. The package structure 1f may include an electrical connection 16 between the metallic layer 62 and the heat dissipating element 50. The metallic layer 62 may be configured to assist in forming the 1-dimensional features 31 during an electroplating process. In some embodiments, the metallic layer 62 may be disposed on or disposed over the surface 21s3 of the electronic component 21. Although FIG. 6 illustrates the metallic layer 62 is disposed over the surfaces 21s2 and 21s3 of the electronic component 21, the surface 21s2 of the electronic component 21 may be exposed from the metallic layer 62 in other embodiments. In some embodiments, the metallic layer 62 may function as a seed layer, which may assist in forming the 1-dimensional feature 31 (or wires). In some embodiments, when the metallic layer 62 serves as a pad to bond with the 1-dimensional feature 31 (or wires), an intermetallic compound (IMC) 64 may be formed and located between the metallic layer 62 and the confining structure 30a. In some embodiments, the IMC 64 may be located between the metallic layer 62 and the 1-dimensional feature 31 (or in some embodiment, nanowires).

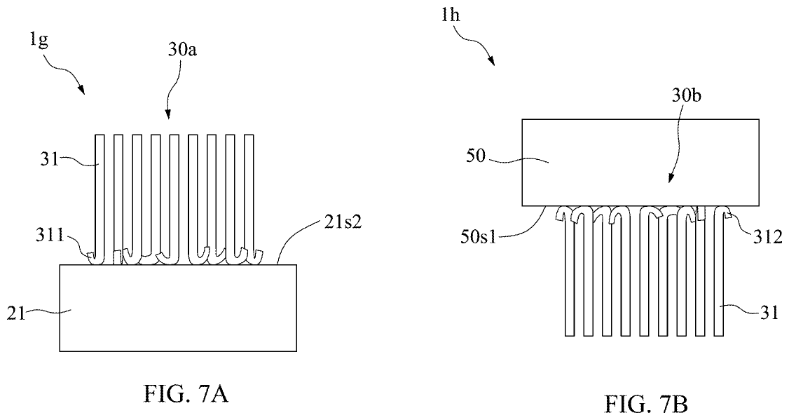

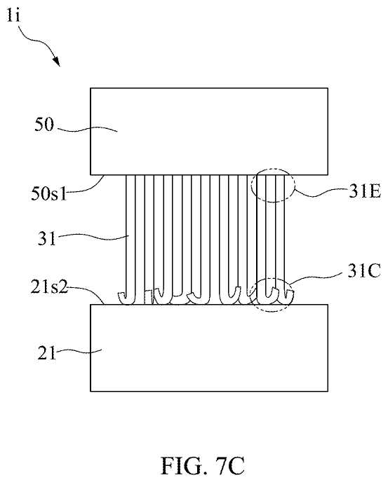

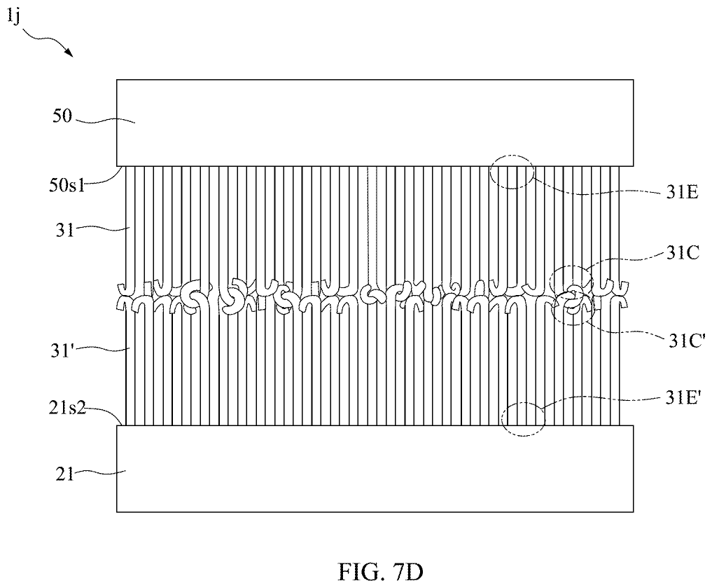

FIG. 7A illustrates a partial enlarged view of an example of a package structure 1g according to some embodiments of the present disclosure. It should be noted that some elements are omitted for brevity.

In some embodiments, the 1-dimensional feature 31 may have a curved end 311 (or a bended portion or a bended end). The curved end 311 may be disposed on or disposed over the surface 21s2 of the electronic component 21. The curved end 311 may be in contact with the electronic component 21. In some embodiments, the curved end 311 may be closer to the electronic component 21 than to the heat dissipating element 50 (not shown in FIG. 7A).

FIG. 7B illustrates a partial enlarged view of an example of a package structure 1h according to some embodiments of the present disclosure. It should be noted that some elements are omitted for brevity.

In some embodiments, the 1-dimensional feature 31 may have a curved end 312 (or a bended portion or a bended end). The curved end 312 may be disposed on or disposed over the surface 50s1 of the heat dissipating element 50. The curved end 312 may be in contact with the heat dissipating element 50. In some embodiments, the curved end 311 may be closer to the heat dissipating element 50 than to the electronic component 21 (not shown in FIG. 7A).

FIG. 7C illustrates a partial enlarged view of an example of a package structure 1i according to some embodiments of the present disclosure. It should be noted that some elements are omitted for brevity.

In some embodiments, the 1-dimensional feature 31 may have an erected end 31E (or an erected portion) and a curved end 31C. In some embodiments, the erected end 31E may extend from the surface 50s1 of the heat dissipating element 50. In some embodiments, the erected end 31E may contact the heat dissipating element 50. In some embodiments, the curved end 31C may contact the electronic component 21.

FIG. 7D illustrates a partial enlarged view of an example of a package structure 1j according to some embodiments of the present disclosure. It should be noted that some elements are omitted for brevity.

In some embodiments, the package structure 1j may further include a 1-dimensional feature 31′. In some embodiments, the 1-dimensional feature 31′ may include a plurality of nanowires. The 1-dimensional feature 31′ may extend from the surface 21s2 of the electronic component 21, and the 1-dimensional feature 31 may extend from the 50s1 of the heat dissipating element 50. In some embodiments, the 1-dimensional feature 31′ may have an erected end 31E′ and a curved end 31C′. In some embodiments, the erected end 31E′ may extend from the surface 21s2 of the electronic component 21. In some embodiments, the curved end 31C′ of the 1-dimensional feature 31′ may contact the curved end 31C of the 1-dimensional feature 31. The 1-dimensional feature 31′ may be entangled with the 1-dimensional feature 31.

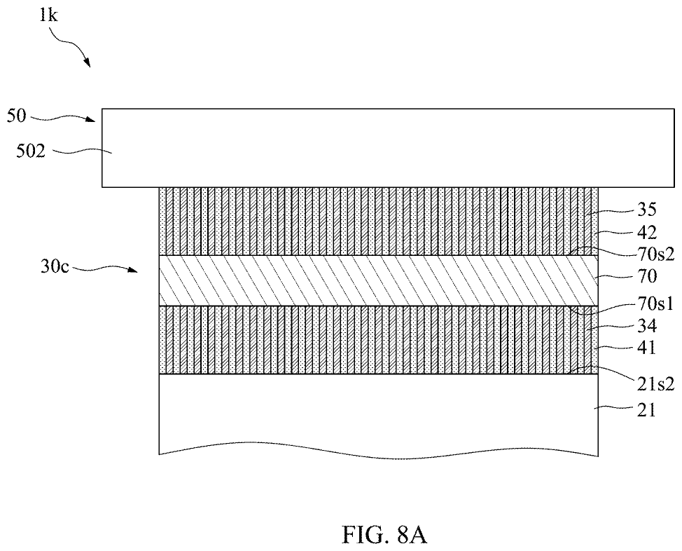

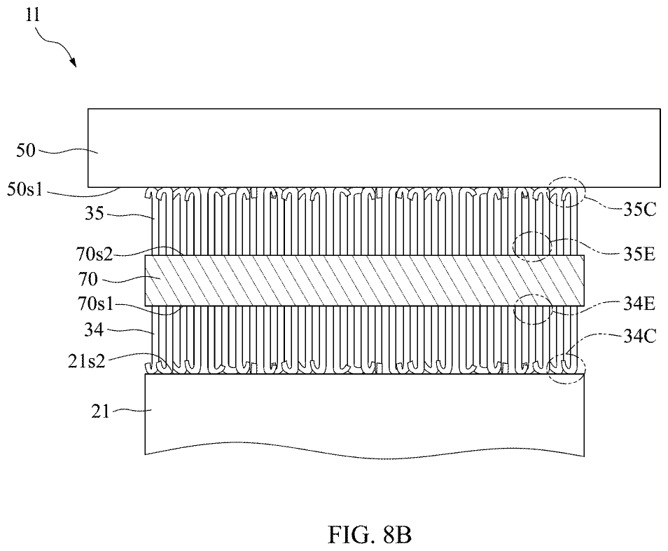

FIG. 8A illustrates a partial enlarged view of an example of a package structure 1k according to some embodiments of the present disclosure. It should be noted that some elements are omitted for brevity.

The package structure 1i may include a confining structure 30c. In some embodiments, the confining structure 30c may include a core 70, 1-dimensional features 34, and 35. The core 70 may be disposed between the electronic component 21 and the heat dissipating element 50. The core 70 may have a surface 70s1 (or a bottom surface) and a surface 70s2 (or a top surface) opposite to the surface 70s1. The core 70 may be configured to function as a carrier on which the 1-dimensional features 34 and 35 are disposed. The core 70 may include a metal, such as indium, aluminum, copper, gold, silver, nickel, or other suitable materials. The core 70 may include metal oxide, such as aluminum oxide, tungsten oxide, titanium oxide, zinc oxide, or other suitable materials.

The 1-dimensional feature 34 may be disposed on or over the surface 70s1 of the core 70. In some embodiments, the 1-dimensional feature 34 may be disposed between the electronic component 21 and the surface 70s1 of the core 70. The composition and the material of the 1-dimensional feature 34 may be the same as or similar to those of the 1-dimensional feature 31. In some embodiments, the 1-dimensional feature 34 may include a plurality of nanowires. In some embodiments, the 1-dimensional feature 34 may be in contact with the electronic component 21. In some embodiments, the 1-dimensional feature 34 may be spaced apart from the heat dissipating element 50 by the core 70. In some embodiments, the nanowires of the 1-dimensional feature 34 may have substantially uniform pitch, which makes the confining structure 30c more robust.

The 1-dimensional feature 35 may be disposed on or over the surface 70s2 of the core 70. The 1-dimensional feature 35 may be disposed between the heat dissipating element 50 and the surface 70s2 of the core 70. The composition and the material of the 1-dimensional feature 35 may be the same as or similar to those of the 1-dimensional feature 31. In some embodiments, the 1-dimensional feature 35 may include a plurality of nanowires. In some embodiments, the 1-dimensional feature 35 may be in contact with the heat dissipating element 50. In some embodiments, the 1-dimensional feature 35 may be spaced apart from the electronic component 21 by the core 70. The 1-dimensional feature 35 may be spaced apart from the 1-dimensional feature 35 by the core 70. In some embodiments, the nanowires of the 1-dimensional feature 35 may have substantially uniform pitch, which makes the confining structure 30c more robust.

The TIM 41 may be disposed on or over the surface 70s1 of the core 70. In some embodiments, the TIM 41 may be disposed between the electronic component 21 and the surface 70s1 of the core 70. In some embodiments, the TIM 41 may be in contact with the electronic component 21. In some embodiments, the TIM 41 may be attached to the 1-dimensional feature 34 by capillary force.

The TIM 42 may be disposed on or over the surface 70s2 of the core 70. In some embodiments, the TIM 42 may be disposed between the heat dissipating element 50 and the surface 70s2 of the core 70. In some embodiments, the TIM 42 may be spaced apart from the TIM 41 by the core 70. In some embodiments, the TIM 42 may be in contact with the heat dissipating element 50. In some embodiments, the TIM 42 may be attached to the 1-dimensional feature 35 by capillary force.

In a comparative example, two adhesive layers are disposed on two opposite sides of a core substrate. Such design requires a core substrate with a relatively great thickness (e.g., 300 μm) to resist warpage of a carrier. In this embodiment, the 1-dimensional features 34 and 35 may serve as a reinforcement structure, which strengthens the overall structure to resist the warpage of a carrier, such as the carrier 10 as shown in FIG. 1. As a result, the core 70 may have a relatively small thickness (e.g., 150 μm or less) without deformation of the heat dissipating element 50. The 1-dimensional features 34 and 35 may be configured to prevent the TIMs 41 and 42 from overflowing to an area exterior to the electronic component 21, which improves the performance of heat transmission.

FIG. 8B illustrates a partial enlarged view of an example of a package structure 1l according to some embodiments of the present disclosure. It should be noted that some elements are omitted for brevity.

In some embodiments, the 1-dimensional feature 34 may have a curved end 34C. In some embodiments, the curved end 34C may contact the electronic component 21. In some embodiments, the 1-dimensional feature 34 may have an erected end 34E. In some embodiments, the erected end 34E may contact the core 70. In some embodiments, the 1-dimensional feature 35 may have a curved end 35C. In some embodiments, the curved end 35C may contact the heat dissipating element 50. In some embodiments, the 1-dimensional feature 35 may have an erected end 35E. In some embodiments, the erected end 35E may contact the core 70.

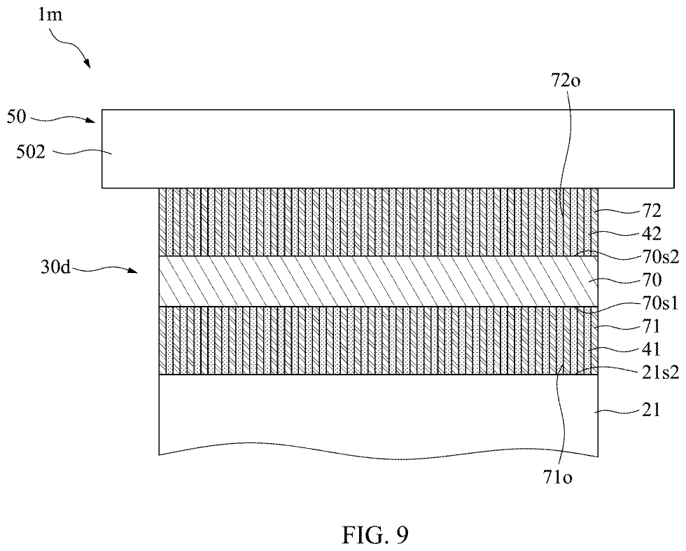

FIG. 9 illustrates a partial enlarged view of an example of a package structure 1m according to some embodiments of the present disclosure. It should be noted that some elements are omitted for brevity.

The package structure 1m may include a confining structure 30d. In some embodiments, the confining structure 30d may include the core 70, 1-dimensional features 71 and 72. The 1-dimensional feature 71 may be disposed on or disposed over the surface 70s1 of the core 70. In some embodiments, the 1-dimensional feature 71 may be in contact with the electronic component 21. The 1-dimensional feature 71 may extend between the core 70 and the electronic component 21. In some embodiments, the 1-dimensional feature 71 may be spaced apart from the heat dissipating element 50 by the core 70. In some embodiments, the 1-dimensional feature 71 may include a nanoporous material (or a nanoporous structure). In some embodiments, the 1-dimensional feature 71 may include a nanoporous scaffold, such as an anodic aluminum oxide (AAO) scaffold or a polymer scaffold. In some embodiments, the material of the 1-dimensional feature 71 may be the same as or similar to that of the core 70. The 1-dimensional feature 71 may include a metal, such as indium, aluminum, copper, gold, silver, nickel, or other suitable materials. The 1-dimensional feature 71 may include metal oxide, such as aluminum oxide, tungsten oxide, titanium oxide, zinc oxide, or other suitable materials. The 1-dimensional feature 71 may define a plurality of openings 710. In some embodiments, the TIM 41 may be disposed within the openings 710 of the 1-dimensional feature 71. In some embodiments, the TIM 41 may be accommodated by or attaching to the 1-dimensional feature 71.

The 1-dimensional feature 72 may be disposed on or disposed over the surface 70s2 of the core 70. In some embodiments, the 1-dimensional feature 72 may be in contact with the heat dissipating element 50. The 1-dimensional feature 72 may be spaced apart from the 1-dimensional feature 71 by the core 70. The 1-dimensional feature 72 may extend between the core 70 and the heat dissipating element 50. In some embodiments, the 1-dimensional feature 72 may include a nanoporous material (or a nanoporous structure). In some embodiments, the 1-dimensional feature 72 may include a nanoporous scaffold, such as an AAO scaffold or a polymer scaffold. In some embodiments, the material of the 1-dimensional feature 72 may be the same as or similar to that of the core 70. The 1-dimensional feature 72 may include a metal, such as indium, aluminum, copper, gold, silver, nickel, or other suitable materials. The 1-dimensional feature 72 may include metal oxide, such as aluminum oxide, tungsten oxide, titanium oxide, zinc oxide, or other suitable materials. The 1-dimensional feature 72 may define a plurality of openings 720. In some embodiments, the TIM 42 may be disposed within the openings 720 of the 1-dimensional feature 72. In some embodiments, the TIM 42 may be accommodated by or attaching to the 1-dimensional feature 72.

In some embodiments, the 1-dimensional feature 72 may include a scaffold defining a nanoporous structure which extends in a primary direction. The directional pores or openings extending in the primary direction can be the 1-dimensional feature in said material. For example, the scaffold includes a plurality of openings 720. The openings 720 may have a circular profile, an elliptical profile, or other suitable profiles from a top view. The openings 720 may have a dimension (e.g., diameter, width, and/or aperture) equal to or less than 1000 nm, such as 1000 nm, 500 nm, 100 nm, 50 nm, 30 nm, 10 nm, 5 nm, or less. The TIM 42 filling into the nanoporous structure may conform to its contour and showing a circular profile, an elliptical profile, or other suitable profiles from a top view.

Similarly, the openings 710 may have a circular profile, an elliptical profile, or other suitable profiles from a top view. The TIM 41 filling into the nanoporous structure may conform to its contour and showing a circular profile, an elliptical profile, or other suitable profiles from a top view.

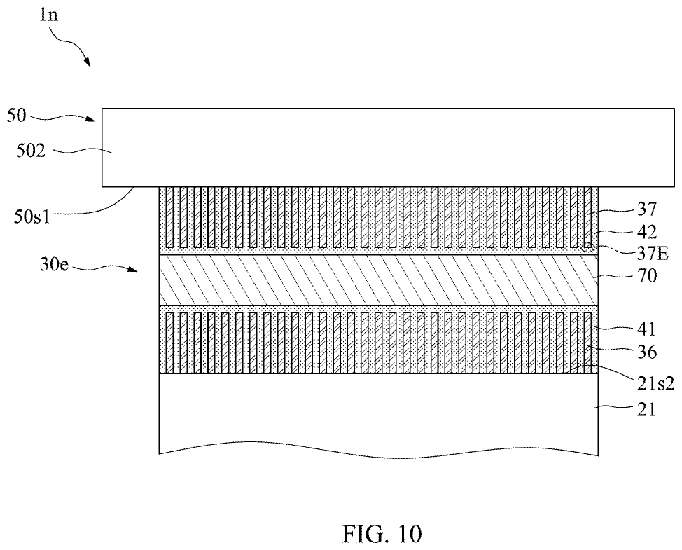

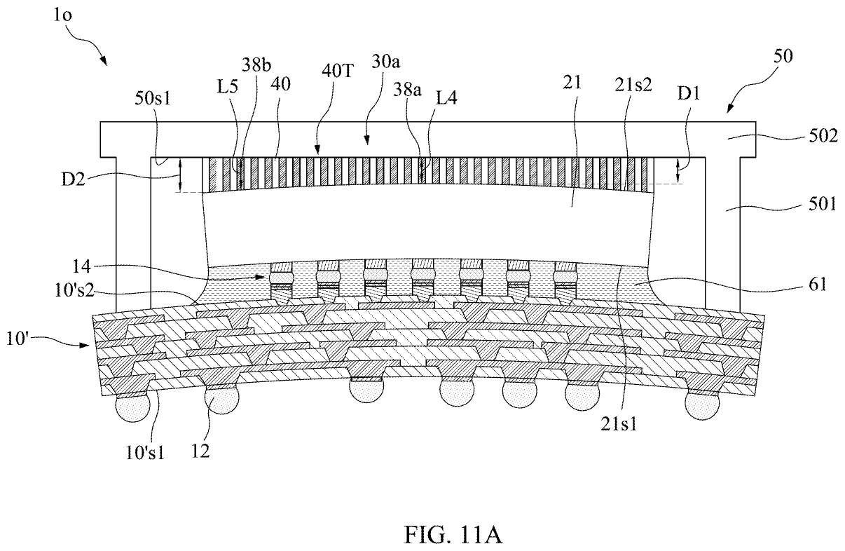

FIG. 10 illustrates a partial enlarged view of an example of a package structure 1n according to some embodiments of the present disclosure. It should be noted that some elements are omitted for brevity.

The package structure 1n may include a confining structure 30e. The confining structure 30e may include 1-dimensional features 36 and 37. The 1-dimensional feature 36 may be disposed on or over the surface 21s2 of the electronic component 21. In some embodiments, the 1-dimensional feature 36 may be spaced apart from the core 70. The composition and the material of the 1-dimensional feature 36 may be the same as or similar to those of the 1-dimensional feature 31. In some embodiments, the 1-dimensional feature 36 may include a plurality of nanowires. In some embodiments, a portion of the TIM 41 may be disposed between the 1-dimensional feature 36 and the core 70.

The 1-dimensional feature 37 may be disposed on or over the surface 50s1 of the heat dissipating element 50. In some embodiments, the 1-dimensional feature 37 may be spaced apart from the core 70. In some embodiments, the 1-dimensional feature 37 may have an end 37E spaced apart from the core 70. The composition and the material of the 1-dimensional feature 37 may be the same as or similar to those of the 1-dimensional feature 31. In some embodiments, the 1-dimensional feature 37 may include a plurality of nanowires. In some embodiments, a portion of the TIM 42 may be disposed between the 1-dimensional feature 37 and the core 70.

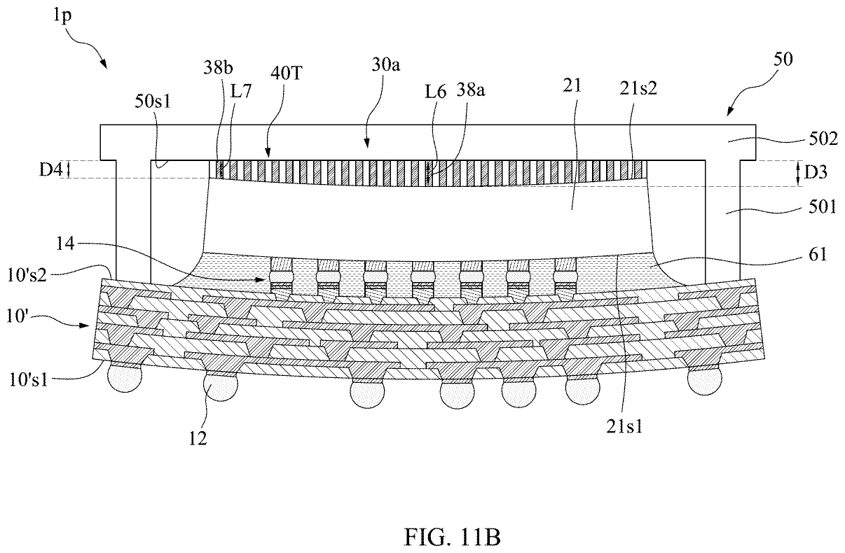

FIG. 11A illustrates a cross-sectional view of an example of a package structure 1o according to some embodiments of the present disclosure. The package structure 1o is similar to the package structure 1a as shown in FIG. 1, and the differences therebetween are described below.

In some embodiments, the package structure 1o may include a carrier 10′, wires 38a and 38b. The carrier 10′ may be the same as or similar to the carrier 10. The carrier 10′ may have a warpage. The carrier 10′ may have a surface 10′s1 and a surface 10′s2. The surface 10′s1 may have a curved surface. For example, the surface 10′s2 may be convex toward the electronic component 21. The electronic component 21 may conform to the warpage of the carrier 10′. For example, the surface 21s1 of the electronic component 21 may be a curved surface. The surface 21s2 of the electronic component 21 may be a curved surface.

The wire 38a may include a nanowire. The wire 38b may include a nanowire. The wire 38a may be disposed over a center portion of the electronic component 21. The wire 38b may be disposed over a peripheral portion of the electronic component 21. The wire 38b is closer to an edge (or a lateral surface) of the electronic component 21 than the wire 38a is. The wires 38a and 38b may overlap the footprint of the electronic component 21. The wire 38a may have a length L4. The wire 38b may have a length L5. In some embodiments, the length L4 is different from the length L5. In some embodiments, the length L4 is less than the length L5. A thickness D1 of the thermal interfacing unit 40T (or thermal conductive uniformer) between the heat dissipating element 50 and the electronic component 21 over a center portion of the electronic component 21 may be different from a thickness D2 of the thermal interfacing unit 40T (or thermal conductive uniformer) between the heat dissipating element 50 and the electronic component 21 over an edge portion of the electronic component 21. The thermal interfacing unit 40T (or thermal conductive uniformer) is in contact with the electronic component 21 conforming to the warpage of the carrier 10′. The bottom of the thermal interfacing unit 40T (or thermal conductive uniformer) may be in contact with the electronic component 21 conforming to the warpage of the carrier 10′.

In this embodiment, the thermal interfacing unit 40T (or thermal conductive uniformer) may function as a reinforcement structure (or a supporting structure), which may compensate the warpage of the carrier 10′. The thermal interfacing unit 40T (or thermal conductive uniformer) may prevent the heat dissipating element 50 being angled with respect to the surface 21s2 of the electronic component 21 even if the carrier 10′ has a relatively large warpage.

FIG. 11B illustrates a cross-sectional view of an example of a package structure according to some embodiments of the present disclosure. The package structure 1p is similar to the package structure 1o as shown in FIG. 11A, and the differences therebetween are described below.

The surface 10′s1 may have a curved surface. For example, the surface 10′s1 may be convex toward a direction far away from the electronic component 21. The electronic component 21 may conform to the warpage of the carrier 10′. The surface 21s1 may be convex toward the carrier 10′.

The wire 38a may have a length L6. The wire 38b may have a length L7. In some embodiments, the length L7 is less than the length L6. A thickness D3 of the thermal interfacing unit 40T (or thermal conductive uniformer) between the heat dissipating element 50 and the electronic component 21 over a center portion of the electronic component 21 may be different from a thickness D4 of the thermal interfacing unit 40T (or thermal conductive uniformer) between the heat dissipating element 50 and the electronic component 21 over an edge portion of the electronic component 21.

In this embodiment, the thermal interfacing unit 40T (or thermal conductive uniformer) may function as a reinforcement structure (or a supporting structure), which may compensate the warpage of the carrier 10′. The thermal interfacing unit 40T (or thermal conductive uniformer) may prevent the heat dissipating element 50 being angled with respect to the surface 21s2 of the electronic component 21 even if the carrier 10′ has a relatively large warpage.

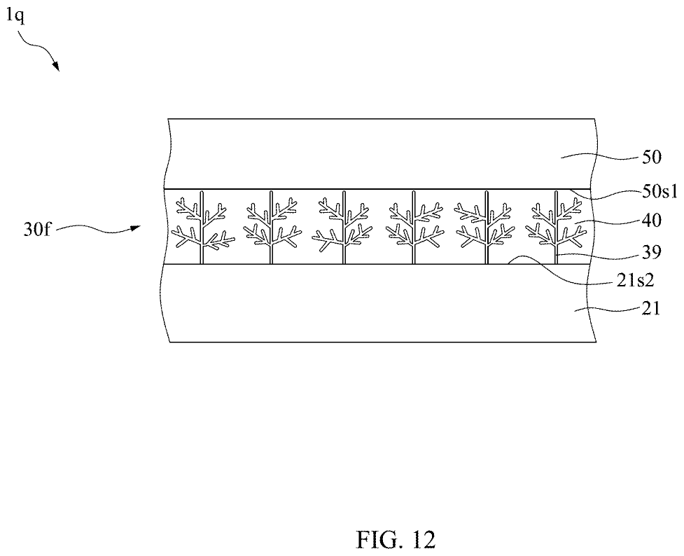

FIG. 12 illustrates a partial enlarged view of an example of a package structure 1q according to some embodiments of the present disclosure.

The package structure 1q may include a confining structure 30f. In some embodiments, the confining structure 30f may include a 1-dimensional feature 39. In some embodiments, the 1-dimensional feature 39 may include a plurality of nanowires. In some embodiments, the 1-dimensional feature 39 may have a dendritic profile. The 1-dimensional feature 39 may provide a relatively great surface. Thus, the capillary force between the 1-dimensional feature 39 and the TIM 40 may be enhanced.

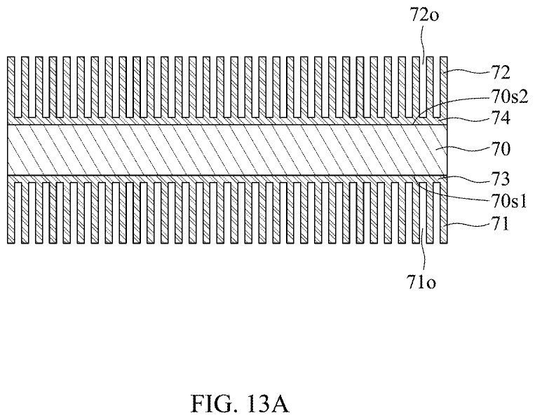

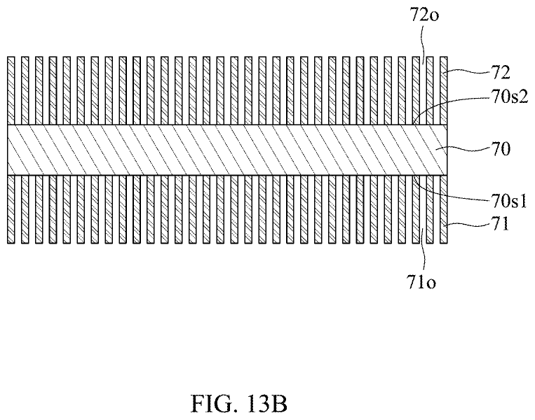

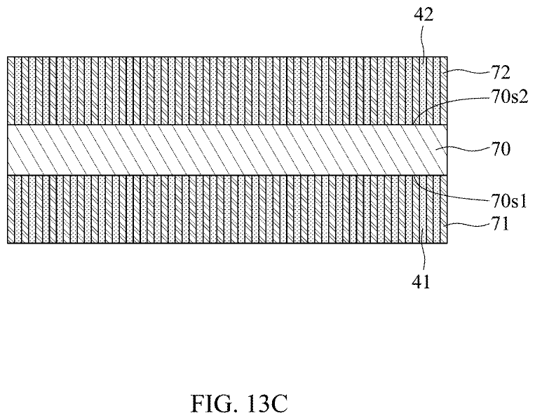

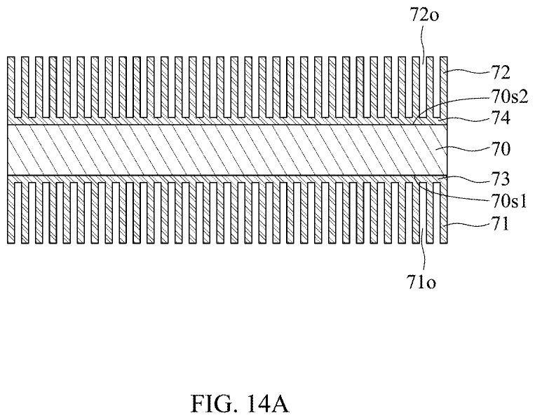

FIG. 13A, FIG. 13B, and FIG. 13C illustrate stages of an example of a method for manufacturing a confining structure according to some embodiments of the present disclosure.

Referring to FIG. 13A, a core 70 may be provided. A 1-dimensional feature 71 may be formed on the surface 70s1 of the core 70. A 1-dimensional feature 72 may be formed on the surface 70s2 of the core 70. The 1-dimensional feature 71 may be connected to the core 70 by a supporting bar 73. The 1-dimensional feature 72 may be connected to the core 70 by a supporting bar 74. In some embodiments, the 1-dimensional feature 71, the 1-dimensional feature 72, the supporting bar 73, and the supporting bar 74 may include or be made of an anodic aluminum oxide (AAO) structure or other suitable structures. In some embodiments, a metal substrate, such as an aluminum substrate, is provided, and an electrochemical technique, such as anodizing technique, is performed on two opposite surfaces of the metal substrate. As a result, a porous structure, which includes openings 710 and 720 as shown in FIG. 13A, may be formed.

Referring to FIG. 13B, the electrochemical technique, such as anodizing technique, may continue until the surfaces 70s1 and 70s2 of the core 70 are exposed. The supporting bars 73 and 74 may be removed.

Referring to FIG. 13C, TIMs 41 and 42 may be formed to fill the openings 710 and 720, respectively. As a result, a thermal interfacing unit, including a confining structure (e.g., 30d) and a TIM(s) (e.g., 41 and 42), as shown in FIG. 9, may be formed.

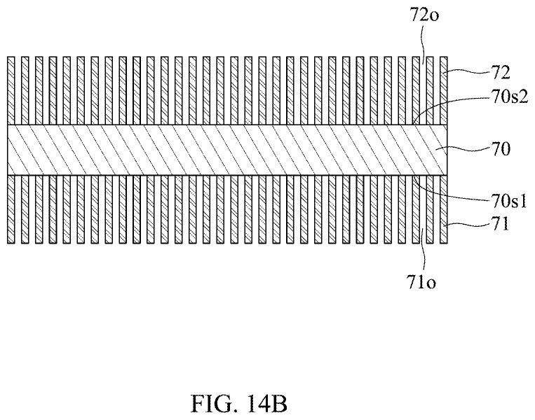

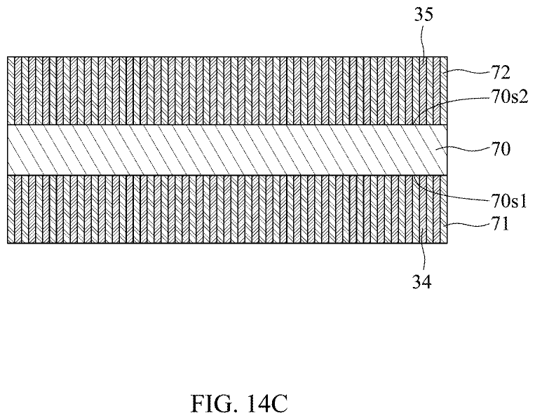

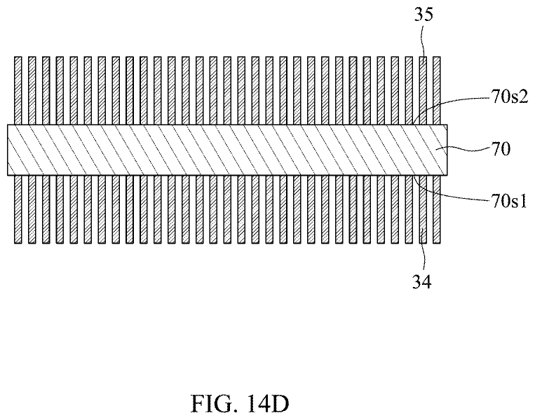

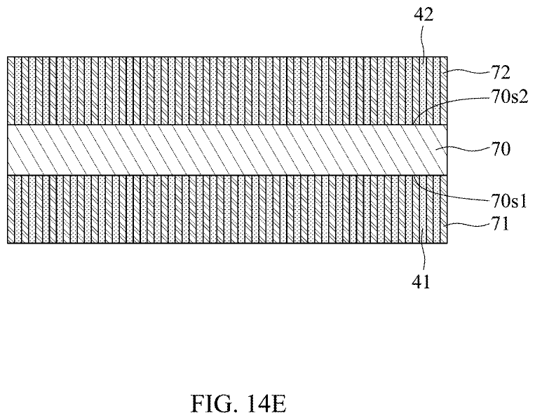

FIG. 14A, FIG. 14B, FIG. 14C, FIG. 14D, and FIG. 14E illustrate stages of an example of a method for manufacturing a confining structure according to some embodiments of the present disclosure.

Referring to FIG. 14A, a core 70 may be provided. A 1-dimensional feature 71 may be formed on the surface 70s1 of the core 70. A 1-dimensional feature 72 may be formed on the surface 70s2 of the core 70. The 1-dimensional feature 71 may be connected to the core 70 by a supporting bar 73. The 1-dimensional feature 72 may be connected to the core 70 by a supporting bar 74. In some embodiments, the 1-dimensional features 71 and 72, as well as the supporting bars 73 and 74 may include or be made of an AAO structure or other suitable structures. In some embodiments, a metal substrate, such as an aluminum substrate, is provided, and an electrochemical technique, such as anodizing technique, is performed on two opposite surfaces of the metal substrate. As a result, a porous structure, which includes openings 710 and 720 as shown in FIG. 14A, may be formed.

Referring to FIG. 14B, the electrochemical technique, such as anodizing technique, may continue until the surfaces 70s1 and 70s2 of the core 70 are exposed. The supporting bars 73 and 74 may be removed.

Referring to FIG. 14C, 1-dimensional features 34 and 35 may be formed within the openings 710 and 720, respectively.

Referring to FIG. 14D, the 1-dimensional features 71 and 72 may be removed from the core 70. In some embodiments, an acid solution or other suitable solutions may be utilized to remove the 1-dimensional features 71 and 72.

Referring to FIG. 14E, a TIM 41 may be formed on the surface 70s1 of the core 70. The TIM 41 may be attached to the 1-dimensional feature 34 by capillary force. A TIM 42 may be formed on the surface 70s2 of the core 70. The TIM 41 may be attached to the 1-dimensional feature 35 by capillary force. As a result, a thermal interfacing unit, including a confining structure (e.g., 30c) and a TIM(s) (e.g., 41 and 42), as shown in FIG. 8A, may be formed.

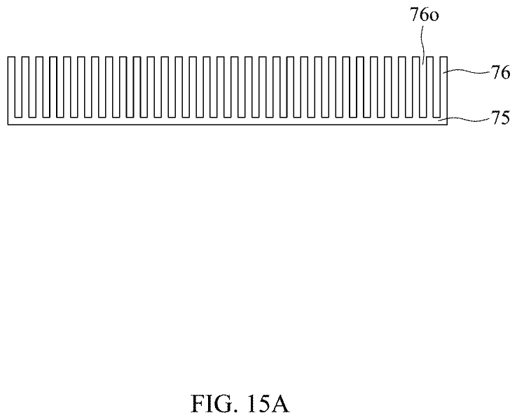

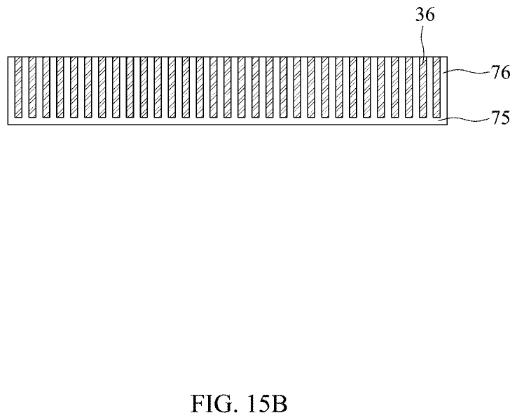

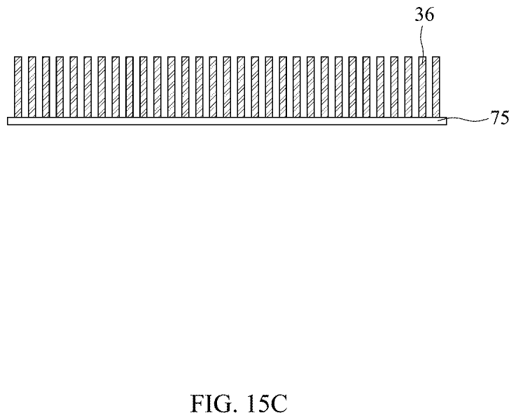

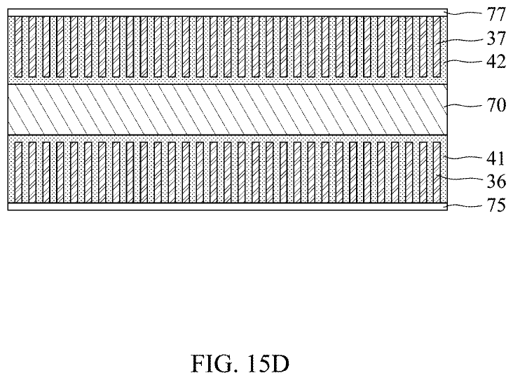

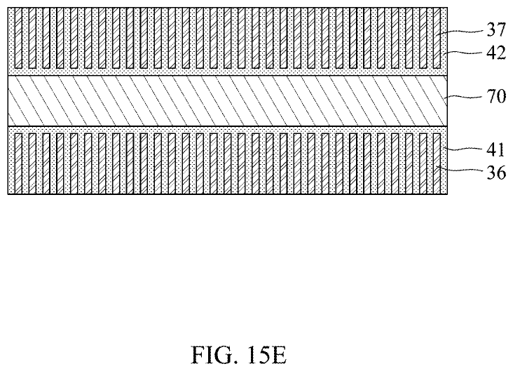

FIG. 15A, FIG. 15B, FIG. 15C, FIG. 15D, and FIG. 15E illustrate stages of an example of a method for manufacturing a confining structure according to some embodiments of the present disclosure.

Referring to FIG. 15A, a carrier 75 may be provided. A 1-dimensional feature 76 may be formed on the carrier 75. In some embodiments, the carrier 75 and the 1-dimensional feature 76 may include or be made of an anodic aluminum oxide (AAO) structure or other suitable structures. In some embodiments, the carrier 75 and the 1-dimensional feature 76 may define a nanoporous scaffold, such as an AAO scaffold or a polymer scaffold. In some embodiments, a metal substrate, such as an aluminum substrate, is provided, and an electrochemical technique, such as anodizing technique, is performed on two opposite surfaces of the metal substrate. As a result, a porous structure, which includes openings 760 as shown in FIG. 15A, may be formed.

Referring to FIG. 15B, a 1-dimensional feature 36 (e.g., nanowires) may be formed within the openings 760.

Referring to FIG. 15C, the 1-dimensional feature 76 may be removed from the carrier 75.

Referring to FIG. 15D, a core 70 may be provided. A TIM 41 may be formed on a surface 70s1 of the core 70. The carrier 75 and the 1-dimensional feature 36 may be inserted into the TIM 41. In some embodiments, the 1-dimensional feature 36 may be spaced apart from the core 70 by the TIM 41. The TIM 41 may be attached to the 1-dimensional feature 36 by capillary force. Similarly, a carrier 77 and a 1-dimensional feature 37 (e.g., nanowires) may be provided. A TIM 42 may be formed on a surface 70s2 of the core 70. The carrier 77 and the 1-dimensional feature 37 may be inserted into the TIM 42. In some embodiments, the 1-dimensional feature 37 may be spaced apart from the core 70 by the TIM 42. The TIM 42 may be attached to the 1-dimensional feature 37 by capillary force.

Referring to FIG. 15E, the carriers 75 and 77 may be removed from the core 70. As a result, a thermal interfacing unit, including a confining structure (e.g., 30e) and a TIM(s) (e.g., 41 and 42), as shown in FIG. 10, may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of arrangements of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no exceeding 5 μm, no exceeding 2 μm, no exceeding 1 μm, or no exceeding 0.5 μm. A surface can be deemed to be substantially flat if a displacement between the highest point and the lowest point of the surface is no exceeding 5 μm, no exceeding 2 μm, no exceeding 1 μm, or no exceeding 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity exceeding approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
an electronic component having an upper surface;
a heat dissipating element over the upper surface of the electronic component;
a thermal interfacing unit between the upper surface of the electronic component and the heat dissipating element, wherein the thermal interfacing unit comprises:
a thermal interfacing material (TIM); and
a confining structure, wherein the TIM is attached to the confining structure by capillary force.

2. The package structure of claim 1, wherein the confining structure comprises a plurality of wires extending along a direction from the electronic component toward the heat dissipating element, and wherein a length of at least one wires measured along the direction is greater than a width of the at least one wires.

3. The package structure of claim 2, wherein at least one wires comprises a bended portion, and the bended portion is closer to the heat dissipating element than to the electronic component along the direction.

4. The package structure of claim 3, further comprising:
a seed layer between the electronic component and the plurality of wires.

5. The package structure of claim 2, wherein the electronic component has an edge portion and a center portion, and wherein at least one wires in the edge portion has a greater bended portion than an erected portion compared to at least one wires in the center portion.

6. The package structure of claim 1, wherein a portion of the confining structure downwardly extend to a lateral side of the electronic component.

7. The package structure of claim 2, wherein the TIM is attached to the plurality of wires and the TIM has a length greater than a width along the direction.

8. The package structure of claim 2, wherein a first portion of the plurality of wires have an erected end extending from the heat dissipating element and a curved end contacting the upper surface of the electronic component.

9. The package structure of claim 1, wherein the heat dissipating element comprises a first portion covering the upper surface of the electronic component and a second portion facing the lateral side of the electronic component, and wherein the confining structure comprises a plurality of wires extending laterally along a direction from the second portion of the heat dissipating element toward the electronic component.

10. The package structure of claim 1, wherein the confining structure further comprises a core having a first surface and a second surface opposite to the first surface, and wherein the confining structure is disposed over the first surface and the second surface.

11. A package structure, comprising:
an electronic component having an upper surface;
a heat dissipating element over the upper surface of the electronic component; and
a supporting structure comprises a plurality of wires configured to reduce the heat dissipating element from being angled with the upper surface of the electronic component.

12. The package structure of claim 11, wherein the plurality of wires have a substantially uniform pitch.

13. The package structure of claim 12, wherein at least one of the plurality of wires comprises a bended portion.

14. The package structure of claim 11, wherein the plurality of wires comprises a first wire with a first length and a second wire with a second length different from the first length, and wherein the first wire and the second wire are overlapping within a footprint of the electronic component.

15. The package structure of claim 11, wherein the supporting structure further comprises a core having a first surface and a second surface opposite to the first surface, and wherein the plurality of wires are disposed over the first surface and the second surface.

16. A package structure, comprising:
a carrier having a warpage;
an electronic component disposed over the carrier and conforming to the warpage;
a heat dissipating element on the carrier and covering the electronic component; and
a thermal conductive uniformer between the electronic component and the heat dissipating element, wherein the thermal conductive uniformer is configured to provide homogeneous thermal conductivity between the electronic component and the heat dissipating element.

17. The package structure of claim 16, wherein the thermal conductive uniformer comprises a 1-dimensional feature and a thermal interfacing material (TIM) accommodated by or attaching to the 1-dimensional feature.

18. The package structure of claim 17, wherein the thermal conductive uniformer comprises a core having a first surface and a second surface opposite to the first surface, and wherein the 1-dimensional feature comprises first wires disposed over the first surface and second wires disposed over the second surface.

19. The package structure of claim 16, wherein a first thickness of the thermal conductive uniformer between the heat dissipating element and the electronic component over a center portion of the electronic component is different from a second thickness of the thermal conductive uniformer between the heat dissipating element and the electronic component over an edge portion of the electronic component.

20. The package structure of claim 16, wherein a bottom of the thermal conductive uniformer is in contact with the electronic component conforming to the warpage of the carrier.
